(19) United States
(12) Patent Application Publication
(10) Pub. No.: US 2026/0362859 A1
(43) Pub. Date: Nov. 12, 2026

(54) PHOSPHOR-LOADED ADHESIVES FOR COVER STRUCTURES

(71) Applicant: CreeLED, Inc., Durham, NC (US)

(72) Inventors: Andre Pertuit, Raleigh, NC (US); Liam Omer, Durham, NC (US)

(21) Appl. No.: 19/201,370

(22) Filed: May 7, 2025

(51) Int. Cl. H10H 20/851; H10H 20/01; H10H 20/85; H10H 20/853

(52) U.S. Cl. CPC H10H 20/851; H10H 20/0361; H10H 20/0362; H10H 20/8502; H10H 20/853

(57) ABSTRACT

Light-emitting diode (LED) components and, more particularly, cover structures for LED components are disclosed. The cover structures have cut-outs for bond pads that are away from the edges of the cover structure, and methods for fabricating the cover structures for the LED components. The cut-outs in the cover structure are enclosed by the non-cut-out portions of the cover structure, i.e., the cut-out portions do not form an outer edge of the cover structure. This can maximize the coverage of the cover structure over the LED chip as well as make it easier to handle the cover structure. Additionally, cut-out portions can be formed in the cover structure prior to attaching and/or mounting the cover structure to the LED package, thus simplifying the fabrication process and avoiding the time-consuming and wasteful exercise of grinding the cover structure to expose the bond pad after the LED chip is bump bonded.

### FIELD OF THE DISCLOSURE

The present disclosure relates to light-emitting diode (LED) components with cover structures, adhesives used to attach these cover structures, and methods for fabricating the same.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new applications, including LED displays and lighting devices for general illumination.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers, where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that can provide mechanical support, electrical connections, and encapsulation for LED emitters. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to light-emitting diode (LED) components, and more particularly, to phosphor-loaded adhesives for cover structures for LED components and methods for fabricating the cover structures for the LED components. In particular, the phosphor load in the adhesive that attaches the cover structure to the LED component may apply a transform function on light passing through the adhesive at the edges of the LED package. The cover structures may include cut-outs that are enclosed by the non-cut-out portions of the cover structure, i.e., the cut-out portions do not form an outer edge of the cover structure. The phosphor load in the adhesive may likewise apply a transform function on light passing through the adhesive at such cut-out portions.

In one aspect, an LED package includes a submount, at least one LED chip on the submount, a loaded adhesive material on the at least one LED chip, wherein the loaded adhesive material is configured to impose a transform function on light emitted by the at least one LED chip and a cover structure attached to the at least one LED chip, the cover structure comprising a cut-out portion that corresponds to a contact on the LED chip, wherein the contact is on a side of the at least one LED chip facing the cover structure, and wherein an edge of the cover structure encloses the cut-out portion. In an aspect, the loaded adhesive material comprises a diffuser particle. In an aspect, the loaded adhesive material comprises a phosphor particle. In an aspect, the loaded adhesive material comprises a reflective particle. In an aspect, the loaded adhesive material comprises a lumiphoric material. In an aspect, the loaded adhesive material comprises a first portion that is not loaded. In an aspect, the loaded adhesive material comprises loading particles positioned proximate an exterior edge of the at least one LED chip. In an aspect, the cover structure is formed from at least one of phosphor in glass (PiG), glass, or sapphire. In an aspect, the cover structure is transparent. In an aspect, the cover structure is configured to provide a white transform function on light passing through the loaded adhesive material. In an aspect, the cover structure is configured to provide a color filter transform function on light passing through the loaded adhesive material. In an aspect, the loaded adhesive material comprises two types of phosphor.

In another aspect, a method for forming an LED package includes forming a cover structure and attaching the cover structure to an LED chip mounted on a submount using a loaded adhesive material configured to impose a transform function on light emitted from the LED chip. In an aspect, the method includes the cover structure comprising a cut-out portion, wherein the cut-out portion corresponds to a contact on the LED chip, wherein the contact is on a side of the LED chip facing the cover structure. In an aspect, the method includes depositing dots of loaded adhesive material proximate an edge of the LED chip.

In an aspect, the method includes the cover structure being at least one of phosphor in glass (PiG), glass, or sapphire. In an aspect, the method includes the cover structure comprising a lumiphoric material. In an aspect, the method includes the loaded adhesive comprising at least one of a diffuser particle, a reflective particle, and a phosphor particle. In an aspect, the method includes the loaded adhesive material comprising at least two types of phosphor particles.

Those skilled in the art will appreciate the scope of the present disclosure and realize additional aspects thereof after reading the following detailed description of the preferred aspects in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of a light-emitting diode (LED) package with a cover structure with a cut-out portion.

FIG. 2 is a top-down view of a light-emitting diode (LED) package with a cover structure with a cut-out portion.

FIG. 3 is a top-down view of another light-emitting diode (LED) package with a cover structure with two cut-out portions.

FIG. 4 is a top-down view of a light-emitting diode (LED) package with a cover structure with an elongated cut-out portion.

FIG. 5 is a top-down view of a light-emitting diode (LED) package with a cover structure with a circular cut-out portion.

FIG. 6A is a side elevational cross-sectional view of an LED package with a loaded adhesive layer according to aspects of the present disclosure.

FIG. 6B is a side elevational cross-sectional view of an LED package with an adhesive layer loaded with two types of particles according to aspects of the present disclosure.

FIG. 7A is a top-down view of an exemplary adhesive placement on an LED chip during LED package manufacture before cover structure placement.

FIG. 7B is a top-down view of the LED package and particularly of the compressed adhesive during LED package manufacture after cover structure placement.

FIGS. 8A-8C illustrate LED packages with different cover structures using the loaded adhesive of the present disclosure.

FIG. 9 is a flow chart of a method for fabricating a cover structure with a cut-out portion according to principles of the present disclosure.

### DETAILED DESCRIPTION

The aspects set forth below represent the necessary information to enable those skilled in the art to practice the aspects and illustrate the best mode of practicing the aspects. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term "and/or" includes any and all combinations of one or more of the associated listed items.

It will be understood that when an element such as a layer, region, or substrate is referred to as being "on" or extending "onto" another element, it can be directly on or extend directly onto the other element, or intervening elements may also be present. In contrast, when an element is referred to as being "directly on" or extending "directly onto" another element, there are no intervening elements present. Likewise, it will be understood that when an element such as a layer, region, or substrate is referred to as being "over" or extending "over" another element, it can be directly over or extend directly over the other element or intervening elements may also be present. In contrast, when an element is referred to as being "directly over" or extending "directly over" another element, there are no intervening elements present. It will also be understood that when an element is referred to as being "connected" or "coupled" to another element, it can be directly connected or coupled to the other element or intervening elements may be present. In contrast, when an element is referred to as being "directly connected" or "directly coupled" to another element, there are no intervening elements present.

Relative terms such as "below" or "above" or "upper" or "lower" or "horizontal" or "vertical" may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms "a," "an," and "the" are intended to include the plural forms as well, unless the context clearly indicates otherwise. It will be further understood that the terms "comprises," "comprising," "includes," and/or "including" when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects are described herein with reference to schematic illustrations of aspects of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) components, and more particularly, to phosphor-loaded adhesives for cover structures for LED components and methods for fabricating the cover structures for the LED components. In particular, the phosphor load in the adhesive that attaches the cover structure to the LED component may apply a transform function on light passing through the adhesive at the edges of the LED package. The cover structures may include cut-outs that are enclosed by the non-cut-out portions of the cover structure, i.e., the cut-out portions do not form an outer edge of the cover structure. The phosphor load in the adhesive may likewise apply a transform function on light passing through the adhesive at such cut-out portions.

Before delving into specific details of various aspects of the present disclosure, an overview of elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes, with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, superlattice structures, undoped layers, cladding layers, contact layers, current-spreading layers, light extraction layers, and elements.

The active LED structure can be fabricated from different material systems, with some material systems being Group III nitride-based material systems. Group III nitrides refer to semiconductor compounds formed between nitrogen (N) and elements in Group III of the periodic table, usually aluminum (Al), gallium (Ga), and/or indium (In) in the form of binary, ternary, and/or quaternary compounds. Other material systems include organic semiconductor materials and other Group III-V systems such as gallium phosphide (GaP), gallium arsenide (GaAs), and related compounds. The active LED structure may be grown on a growth substrate that can include many materials, such as sapphire, silicon carbide (SiC), silicon, aluminum nitride (AlN), and GaN.

Different aspects of the active LED structure can emit different wavelengths of light depending on the composition of the active layer. In certain aspects, the active LED structure emits blue light with a peak wavelength range of approximately 430 nanometers (nm) to 480 nm. In other aspects, the active LED structure emits green light with a peak wavelength range of 500 nm to 570 nm. In other aspects, the active LED structure emits red light with a peak wavelength range of 600 nm to 700 nm. In certain aspects, the active LED structure may be configured to emit light that is outside the visible spectrum, including one or more portions of the ultraviolet (UV) spectrum, or one or more portions of the near infrared spectrum, and/or the infrared spectrum (e.g., 700 nm to 1000 nm). The UV spectrum is typically divided into three wavelength range categories denoted with letters A, B, and C. In this manner, UV-A light is typically defined as a peak wavelength range from 315 nm to 400 nm, UV-B light is typically defined as a peak wavelength range from 280 nm to 315 nm, and UV-C light is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphoric material receiving at least a portion of the light generated by the LED source may re-emit light having a different peak wavelength than the LED source. An LED source and one or more lumiphoric materials may be selected such that their combined output results in light with one or more desired characteristics, such as color, color point, intensity, etc. In certain aspects, aggregate emissions of LED chips, optionally in combination with one or more lumiphoric materials, may be arranged to provide cool white, neutral white, or warm white light, such as within a color temperature range of 2,500 Kelvin (K) to 10,000 K. In certain aspects, lumiphoric materials having cyan, green, amber, yellow, orange, and/or red peak emission wavelengths may be used. In some aspects, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain aspects, lumiphoric materials may be downconverting or upconverting, and combinations of both downconverting and upconverting materials may be provided. In certain aspects, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations.

In certain aspects, one or more lumiphoric materials may be provided as a portion of a wavelength conversion element or cover structure that is provided over an LED chip. Wavelength conversion elements or cover structures may include a support element and one or more lumiphoric materials that are provided by any suitable means, such as by coating a surface of the support element or by incorporating the lumiphoric materials within the support element. In certain aspects, the support element may be composed of a transparent material, a semi-transparent material, or a light-transmissive material, such as sapphire, SiC, silicone, and/or glass (e.g., borosilicate and/or fused quartz). Wavelength conversion elements and cover structures may also include ceramic phosphor plates, phosphor-in-glass structures, and/or single crystal phosphors. Support elements as used herein may also be referred to as superstrates to avoid confusion with substrates of LED chips.

Wavelength conversion elements and cover structures of the present disclosure may be formed from a bulk material, which is optionally patterned and then singulated. In certain aspects, the patterning may be performed by an etching process (e.g., wet or dry etching), or by another process that otherwise alters a surface, such as with a laser or saw. In certain aspects, wavelength conversion elements and cover structures may be thinned before or after the patterning process is performed. In certain aspects, wavelength conversion elements and cover structures may comprise a generally planar upper surface that corresponds to a light emission area of the LED package. Phosphor-in-glass or ceramic phosphor plate arrangements may be formed by mixing phosphor particles with glass frit or ceramic materials, pressing the mixture into planar shapes, and firing or sintering the mixture to form a hardened structure that can be cut or separated into individual wavelength conversion elements. Wavelength conversion elements and cover structures may be attached to one or more LED chips using, for example, a layer of transparent adhesive such as silicone.

As used herein, a layer or region of a light-emitting device may be considered to be "transparent" when at least 80% of emitted radiation that impinges on the layer or region emerges through the layer or region. Moreover, as used herein, a layer or region of an LED is considered to be "reflective" or embody a “mirror” or a "reflector" when at least 80% of the emitted radiation that impinges on the layer or region is reflected. In some aspects, the emitted radiation comprises visible light such as blue and/or green LEDs with or without lumiphoric materials. In other aspects, the emitted radiation may comprise nonvisible light. For example, in the context of GaN-based blue and/or green LEDs, silver (Ag) may be considered a reflective material (e.g., at least 80% reflective).

The present disclosure can be useful for LED chips having a vertical geometry. A vertical geometry LED chip typically includes anode and cathode connections on opposing sides or faces of the LED chip. In an aspect, there can be a bond pad for an electrode to connect to on a top of the chip opposite a side of the LED chip facing the submount.

According to aspects of the present disclosure, LED packages may include one or more elements, such as lumiphoric materials, encapsulants, light-altering materials, lenses, and electrical contacts, among others, that are provided with one or more LED chips. In certain aspects, an LED package may include a support structure or support element, such as a lead frame structure or a submount. Lead frame structures are typically at least partially encased by a body or housing. A lead frame structure may typically be formed of a metal, such as copper, copper alloys, or other conductive metals. The lead frame structure may initially be part of a larger metal structure that is singulated during the manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics etc. The housing may be formed on the lead frame structure before singulation so that the individual lead frame portions may be electrically isolated from one another and mechanically supported by the housing within an individual LED package. The housing may form a cup or a recess in which one or more LED chips may be mounted to the lead frame at a floor of the recess. Portions of the lead frame structure may extend from the recess and through the housing to protrude or be accessible outside of the housing to provide external electrical connections. An encapsulant material, such as silicone, epoxy, or polymethyl methacrylate (PMMA), among others, may fill the recess to encapsulate the one or more LED chips. In certain aspects, one or more lumiphoric materials, such as phosphor particles, may be integrated or otherwise embedded within the encapsulant material.

Submount structures typically include submounts with electrically conductive traces. Exemplary submount materials include ceramic materials such as aluminum oxide or alumina, AlN, or organic insulators like polyimide (PI) and polyphthalamide (PPA). In certain aspects, submounts may comprise a printed circuit board (PCB), sapphire, Si or any other suitable material. For PCB aspects, different PCB types can be used such as standard FR-4 PCB, metal core PCB, or any other type of PCB. Light-altering materials may be arranged within LED packages to reflect or otherwise redirect light from the one or more LED chips in a desired emission direction or pattern. Encapsulant materials may be formed to cover LED chips and portions of the submount, and in certain aspects, encapsulant materials may form lenses that direct light in desired emission directions and/or patterns.

Light-altering materials may be arranged within LED packages, such as within housings and/or within portions of recesses thereof, to reflect or otherwise redirect light from the one or more LED chips in a desired emission direction or pattern. As used herein, light-altering materials may include many different materials, including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain aspects, the light-altering material may comprise a generally white color to reflect and redirect light. In other aspects, the light-altering material may comprise a generally opaque color, such as black or gray for absorbing light and increasing contrast. In certain aspects, the light-altering material includes both light-reflective material and light-absorbing material suspended in a binder.

In conventional LED packages for vertical geometry chips, the cover structure is mounted to the LED package over the LED chip with an adhesive that is generally clear silicone. The adhesive has a non-zero thickness, creating a “gap” around the periphery of the LED package between the LED chip and the cover structure through which light from the LED chip may be transmitted in an undesirable fashion. Additionally, if the cover structure includes a cut-out portion, there may be similar gaps around the periphery of the cut-out portion.

To solve these problems, the LED package uses a phosphor-loaded adhesive that imposes a transform function on light passing therethrough to modify the emissions back to a desired profile. In exemplary aspects, the phosphor loading may be only in places proximate an exposed edge (either an outer periphery or a cut-out periphery).

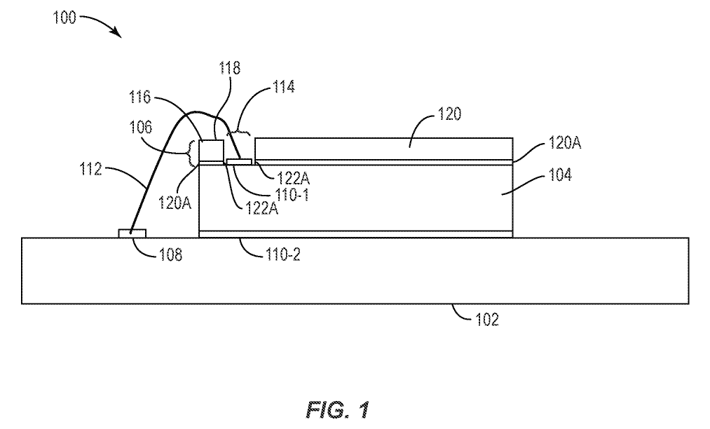

FIG. 1 is a cross-sectional view of a light-emitting diode (LED) package 100 formed from a submount 102 on which an LED chip 104 is positioned. A cover structure 106 is attached to a light-emitting surface of the LED chip 104 using an adhesive layer 120. Conventionally, the adhesive layer 120 is a clear silicone, and light from the LED chip 104 may leak or otherwise be emitted at a peripheral edge gap 120A.

Further, the cover structure 106 may have a cut-out portion 114. The cut-out portion 114 accommodates a vertical contact geometry for the LED chip 104 by providing access to bond pad 110-1, which is the electrode or contact on a first side of the LED chip 104. The LED chip 104 includes another bond pad 110-2, which is the electrode or contact on the opposite side of the LED chip 104, the side which is also attached to the submount 102. The cover structure 106 includes the cut-out portion 114 to enable the wire bond 112 to make contact with the bond pad 110-1, and the wire bond 112 is also connected to trace 108 on the submount 102.

The cover structure 106 may be formed by any combination of one or more of a lumiphoric material, a support element or superstrate, an antireflective layer, a reflective layer, or a filter layer. In certain aspects, any of the lumiphoric material, the superstrate, the antireflective layer, the reflective layer, and the filter layer may be omitted. In some aspects, the cover structure 106 could be used for white conversion or could be an optical filter or lens. In some aspects, the cover structure 106 could be formed from a phosphor sheet, or could be glass, sapphire, or a PiG (phosphor in glass), or a phosphor layer on glass. For aspects without wavelength conversion, the cover structure 106 may comprise a support element or superstrate, such as glass or sapphire, and may be devoid of lumiphoric materials.

Depending on the structure of the LED chip 104, the bond pad 110-1 may be alternatively be a contact configured as either the anode or the cathode for the LED chip 104, while the bond pad 110-2 may be configured as a contact that provides the other of the anode or the cathode.

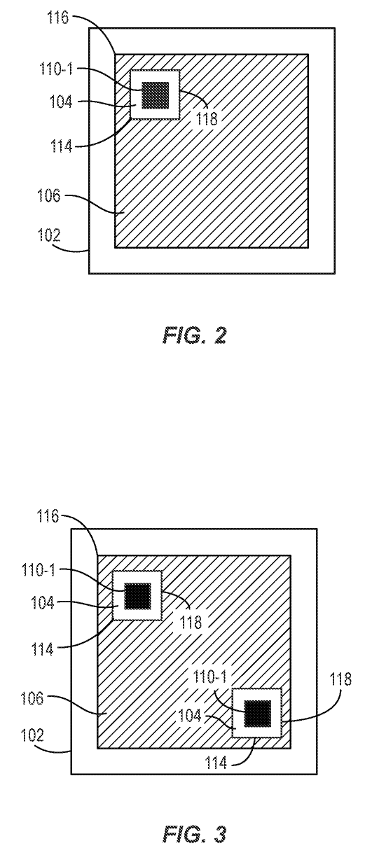

In an aspect, the cut-out portion 114 can be within the cover structure 106 – in other words, the cut-out portion 114 does not extend to a perimeter edge 116 of the cover structure 106. This positioning can be seen more clearly in FIG. 2. Another way of defining this positioning is that an interior edge 118 of the cover structure 106 encircles or encloses the cut-out portion 114. Light may also leak or be emitted through the gap 122A in such interior edge 118.

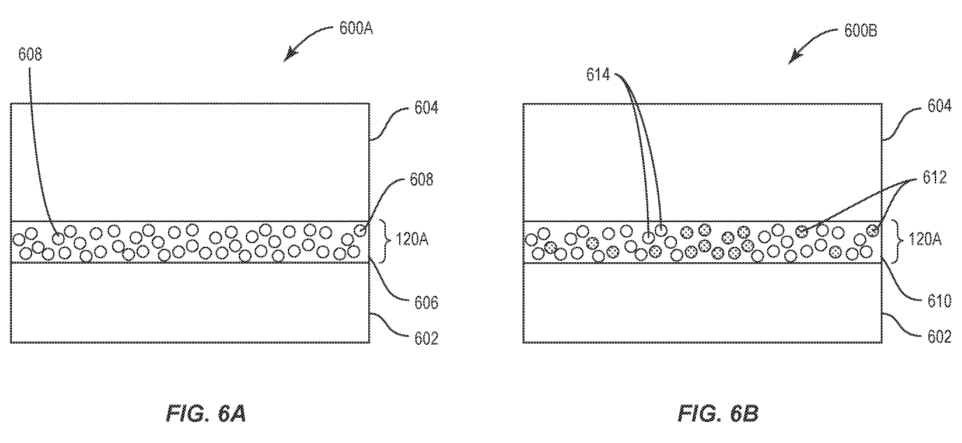

Aspects of the present disclosure contemplate loading the adhesive material with light-altering material and particularly contemplate adding phosphor to impose a transform function on light passing through the gaps 120A and 122A. FIGS. 2-5 illustrate a few different types of cut-out portions. It should be appreciated that this transform function will apply regardless of the shape of the cut-out portion. Likewise, while the above discussion and the discussion of FIGS. 2-5, assume such an interior positioning of the cut-out portion 114, the present disclosure is not so limited, and the teachings provided herein are also applicable to positionings where the cut-out portion 114 extends to the perimeter edge 116. Such a positioning is not shown but is within the scope of the present disclosure. A discussion of particulars of the adhesive begins below with reference to FIG. 6.

FIG. 2 is a top-down view of a light-emitting diode (LED) package with a cover structure with a cut-out portion 114. The aspect in FIG. 2 corresponds to the LED package 100 of FIG. 1, where the cut-out portion 114 is near the perimeter edge 116 of the cover structure 106, but does not extend to the perimeter edge 116. Instead, an edge or interior edge 118 of the cut-out portion 114 encloses the cut-out portion 114 entirely. The position of the cut-out portion 114 corresponds to the position of the bond pad 110-1 and enables the wire bond 112 to make contact with the bond pad 110-1 directly. In an aspect, the wire bond 112 can make contact with a secondary bump bond that can be placed on the bond pad 110-1 before or after placement of the cover structure 106. In some aspects, a portion of the LED chip 104 may be uncovered by the cut-out portion 114, but this can be minimized to increase the amount of light that passes through the cover structure 106.

In the aspect shown in FIG. 2, the cut-out portion 114 can be near a corner of the cover structure 106, but in other aspects, the cut-out portion 114 at an edge or can be anywhere within the cover structure 106. Additionally, in the aspect shown in FIG. 2, the cut-out portion 114 is square, but other shapes are possible too in other aspects, including but not limited to: rectangular, circular, oval, etc.

FIG. 3 is a top-down view of another light-emitting diode (LED) package with a cover structure with two cut-out portions. In the aspect shown in FIG. 3, there are two cut-out portions 114, but in other aspects, there can be three or more. Additionally, while in the aspect in FIG. 3, the cut-out portions 114 are in opposite corners. In other aspects, they could be closer together, near the same corner, or in adjacent corners.

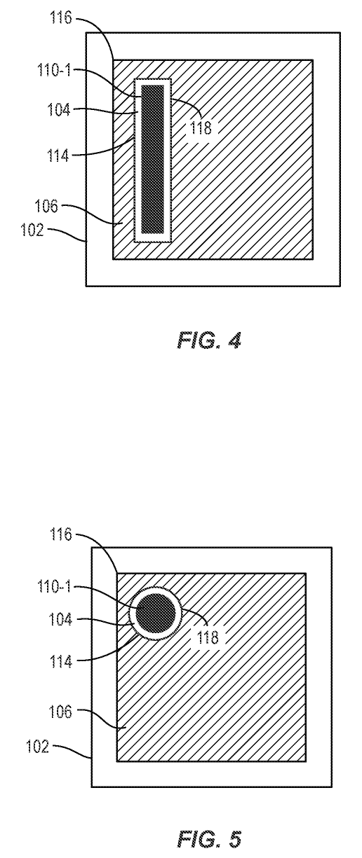

FIG. 4 is a top-down view of a light-emitting diode (LED) package with a cover structure 106 with an elongated cut-out portion 114. In an aspect, the cut-out portion 114 need not be a quadrilateral but could be any size or shape. For example, the cut-out portion 114 could be sized and shaped to accommodate a secondary part of the LED package 100, such as an electrostatic discharge (ESD) diode.

FIG. 5 is a top-down view of a light-emitting diode (LED) package with a cover structure 106 with a circular cut-out portion. The circular shape of the cut-out portion 114 can be configured to correspond to a circular bond pad 110-1, and to minimize an amount of the LED chip 104 that is visible through the cut-out portion 114.

Against the backdrop of different types of cut-out portions, further aspects of the present disclosure are provided. In particular, FIGS. 6A & 6B illustrate cross-sectional views of LED packages 600A & 600B, respectively. The LED package 600A includes an LED chip 602 with a cover structure 604 attached thereto by an adhesive layer 606. In an exemplary aspect, the adhesive layer 606 comprises silicone and includes particles 608 that impose a transform function on light passing therethrough. In the LED package 600A, all the particles 608 are generally the same in function (e.g., all reflective, all phosphor, or all diffuser particles).

In contrast, the LED package 600B includes an adhesive layer 610 that includes heterogenous particles 612, 614. In exemplary aspects, the heterogeneous particles are both phosphor and diffuser particles. Alternatively, a color filtering lumiphoric particle could be used that absorbs only specific wavelengths of light.

By design, the particles 608, 612, 614, are present in sufficient density that some amount of light that would otherwise be emitted by the gap 120A is subjected to the intended transform function. Thus, while, for example, it is possible that a majority of the light be converted, there may also be cases in which converting even a minority of the light would be sufficient to achieve a desired effect. In an exemplary aspect, this density is achieved by including the particles 608, 612, 614 uniformly throughout the adhesive layer 606, 610. However, inclusion of such a prevalence of particles may be undesirable for any number of reasons, and the present disclosure may operate without such uniformity.

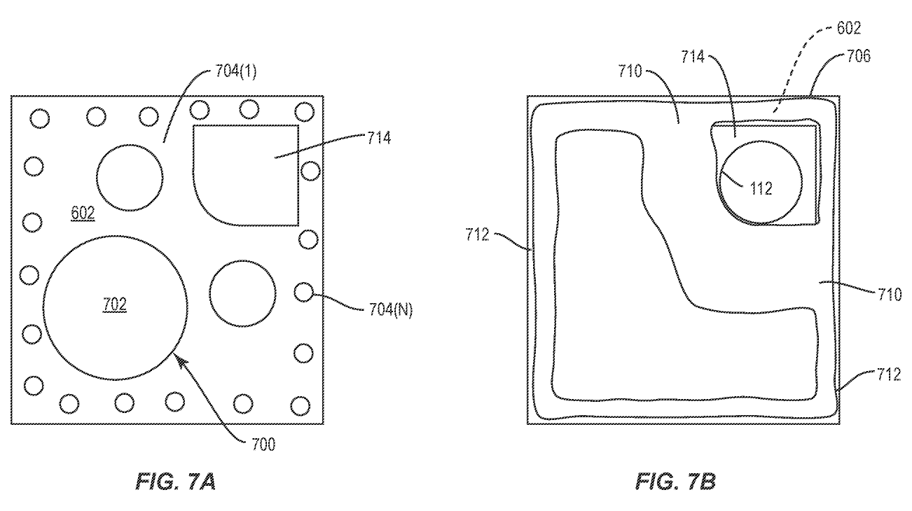

Thus, as illustrated in FIGS. 7A & 7B, it may be possible to position a first portion 700 of adhesive material 702 (which is analogous to adhesive layer 606 or 610) on an LED chip 602, where the first portion 700 has no particles therein. However, proximate interior edges 118 and external edge, second portions 704(1)-704(N) may include loading particles as previously described. FIG. 7A illustrates the deposition of the portions 700, 704(1)-704(N) during manufacture and then when a cover structure 706 is added to form the next step of the LED package assembly, the portions 700, 704(1)-704(N) compress (or more prosaically – squash) and spread as better seen in FIG. 7B. The first portion 700 acts to provide adhesion in a central region while the portions 704(1)-704(N) merge to form an outer ring 710 that provides an outer periphery 712 of loaded adhesive. The adhesive may spread onto a bond pad region 714 so that interior edge 118 is likewise sealed, such that light has to pass through the loaded adhesive.

As discussed above, the loading particles may be phosphors to achieve a color shift, multiple phosphors (e.g., two, three, or four) to match a desired color point, or a reflective particle (e.g., TiO2).

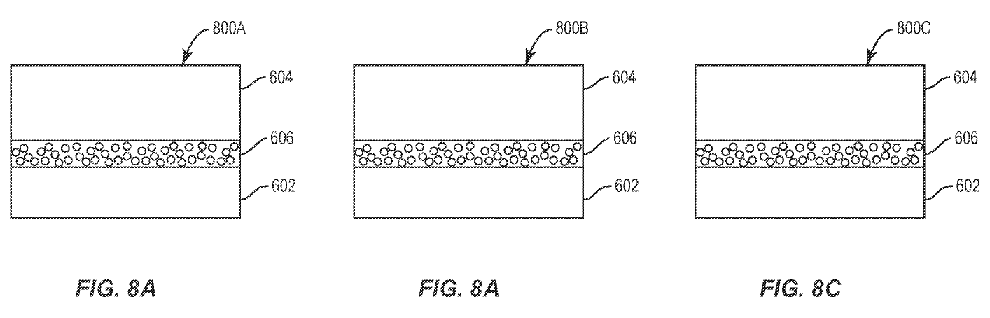

FIGS. 8A-8C illustrate different cover structures 800A-800C. Cover structure 800A is a white conversion cover structure. That is, the cover structure 800A is configured to impose a white transform function on light passing through the loaded adhesive. Cover structure 800B is a transparent cover structure. Cover structure 800C is a color filter cover structure. That is, the cover structure 800C is configured to impose a color transform function on light passing through the loaded adhesive. Aspects of the present disclosure work with any of these cover structures. Likewise, aspects of the present disclosure work with any sort of cut-out portions. Still further, a bump bond may be placed on a bond pad so that when the compression occurs, the adhesive cannot overwhelm the bond pad, and there is still a place to wirebond without having to cut through the adhesive.

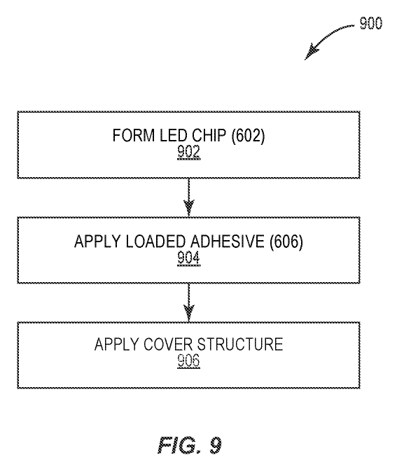

FIG. 9 is a flow chart of a method for fabricating an LED package according to principles of the present disclosure.

At step 902, the method includes forming an LED chip 602.

At step 904, a loaded adhesive layer (606) is applied. This may include adding portions that are not loaded as well as the loaded adhesive.

At step 906, a cover structure is applied and compresses the adhesive to spread the loaded adhesive in such a manner as to subject all light from the LED chip 602 to the transform function of the loaded adhesive before exiting from a gap between the LED chip and the cover structure.

It is contemplated that any of the foregoing aspects, and/or various separate aspects and features as described herein, may be combined for additional advantage. Any of the various aspects as disclosed herein may be combined with one or more other disclosed aspects unless indicated to the contrary herein.

Those skilled in the art will recognize improvements and modifications to the preferred aspects of the present disclosure. All such improvements and modifications are considered within the scope of the concepts disclosed herein and the claims that follow.

What is claimed is:

1. A light-emitting diode (LED) package, comprising:
a submount;
at least one LED chip on the submount;
a loaded adhesive material on the at least one LED chip, wherein the loaded adhesive material is configured to impose a transform function on light emitted by the at least one LED chip; and
a cover structure attached to the at least one LED chip by the loaded adhesive material.

2. The LED package of claim 1 wherein the cover structure comprises a cut-out portion that corresponds to a contact on the at least one LED chip, wherein the contact is on a side of the at least one LED chip facing the cover structure, and wherein an edge of the cover structure encloses the cut-out portion.

3. The LED package of claim 1, wherein the loaded adhesive material comprises a diffuser particle.

4. The LED package of claim 1, wherein the loaded adhesive material comprises a phosphor particle.

5. The LED package of claim 1, wherein the loaded adhesive material comprises a reflective particle.

6. The LED package of claim 1, wherein the loaded adhesive material comprises a lumiphoric material.

7. The LED package of claim 1, wherein the loaded adhesive material comprises a first portion that is not loaded.

8. The LED package of claim 7, wherein the loaded adhesive material comprises loading particles positioned proximate an exterior edge of the at least one LED chip.

9. The LED package of claim 1, wherein the cover structure is formed from at least one of phosphor in glass (PiG), glass, or sapphire.

10. The LED package of claim 1, wherein the cover structure is transparent.

11. The LED package of claim 1, wherein the cover structure is configured to provide a white transform function on light passing through the loaded adhesive material.

12. The LED package of claim 1, wherein the cover structure is configured to provide a color filter transform function on light passing through the loaded adhesive material.

13. The LED package of claim 1, wherein the loaded adhesive material comprises two types of phosphor.

14. A method for forming an LED package, comprising:
forming a cover structure; and
attaching the cover structure to an LED chip mounted on a submount using a loaded adhesive material configured to impose a transform function on light emitted from the LED chip.

15. The method of claim 14, wherein the cover structure comprises a cut-out portion, wherein the cut-out portion corresponds to a contact on the LED chip, wherein the contact is on a side of the LED chip facing the cover structure.

16. The method of claim 14, further comprising depositing dots of loaded adhesive material proximate an edge of the LED chip.

17. The method of claim 14 wherein the cover structure is at least one of phosphor in glass (PiG), glass, or sapphire.

18. The method of claim 14, wherein the cover structure comprises a lumiphoric material.

19. The method of claim 14, wherein the loaded adhesive material comprises at least one of a diffuser particle, a reflective particle, and a phosphor particle.

20. The method of claim 14, wherein the loaded adhesive material comprises at least two types of phosphor particles.
